(19) United States
(12) Patent Application Publication
(10) Pub. No.: US 2016/0068397 A1
(43) Pub. Date: Mar. 10, 2016

(54) Apparatus and method for continuous synthesis of carbon film or inorganic material film

(71) Applicant: National Central University, Taoyuan City (TW)

(72) Inventors: Ching-Yuan Su, Taichung City (TW); Yu Min Chen, Yunlin County (TW)

(21) Appl. No.: 14/846,218

(22) Filed: Sep. 4, 2015

(30) Foreign Application Priority Data
Sep. 4, 2014 (TW) 103130541

(51) Int. Cl. C01B 31/04; C23C 16/46; C23C 16/511; H01J 37/32; C23C 16/26

(52) U.S. Cl. CPC C01B 31/0453; H01J 37/3277; H01J 37/32449; H01J 37/32192; C23C 16/26; C23C 16/511; C23C 16/46; C23C 16/466; H01J 2237/2001; H01J 2237/327; H01J 2237/3321

(57) ABSTRACT

An apparatus for continuous synthesis of carbon film or inorganic material film includes an external chamber having a gas intake gate and a gas exhaust gate; a substrate transporting apparatus disposed inside the external chamber and including a rolling-out member, a plurality of rollers, a rolling-in member, and a moving path; a substrate with metal conveyed along the moving path; a temperature controller correspondingly disposed above or under the substrate transporting apparatus, wherein when the substrate with metal passes through the temperature controller, the temperature controller heats the substrate with metal; a vacuum system connected to the external chamber and inhaling a gas through the gas intake gate and exhausting the gas through the gas exhaust gate; and a gas source controller connected to the external chamber and controlling a supply of the gas, wherein the gas includes a carbon source or an inorganic material source.

### BACKGROUND

1. Technical Field

The technical field relates to an apparatus and a method for continuously synthesizing carbon film or inorganic material film, particularly to an apparatus and method for continuous synthesis of carbon film or inorganic material film in large area.

2. Related Art

Graphene is a single atomic layer graphite which has two-dimensional structure and many superior characteristics, such as high carrier mobility, high mechanical strength, and high thermal conductivity.

Nowadays, many graphene synthesis methods has been disclosed, which includes (1) a mechanical exfoliation method; (2) an epitaxial growth method; (3) a chemical vapor deposition (CVD) method: processed in catalytic metal (such as copper, nickel, iron, etc.); (4) a chemical exfoliation method: using graphite oxide to obtain graphene oxide (GO).

Even though the mechanical exfoliation method and the epitaxial growth method can obtain high-quality graphene (low-defect structure); however, large area synthesis still cannot be achieved. The CVD method, for example, by using Ni and Cu substrate, especially the Cu substrate processing, has been the main producing method for synthesizing the large-area graphene. The recent research using CVD method and the substrate with catalytic metal of Ni/Cu has been successfully produced large-area and high-quality graphene (Reina, A. et. al., Nano Letters 2008, 9, 30-35; Li, X. et. al., Science 2009, 324, 1312-1314; Sukang, B., et. al., Nature; Nanotechnology, 2010, 5, 574-578).

However, Byun, S. J. et. al. use Ni substrate and chemical vapor deposition method to synthesize graphene (Byun, S. J. et. al., The Journal of Physical Chemistry Letters 2011, 2, 493-497), where the as-formed solid solution of the carbon source or the inorganic material source and the Ni metal under high temperature will happen. And also, during the cooling process, the carbon atom will deposit on the surface of the Ni substrate and being reconstructed as a graphene structure. This method cannot precisely control the amount of the deposited carbon atoms, thus the layers of the graphene cannot be precisely controlled.

The synthesis method of using the Cu substrate can obtain large-area and almost single-layer carbon film or inorganic material film (larger than 90% coverage), therefore, it has better controllability regarding the uniformity and the thickness. For the current technique status, as mentioned above, the CVD synthesis method using Cu as substrate has the advantages of good quality, large area, and good controllability (Nano Letters, 2009, 9, 4268.).

However, the pre-treatment temperature of those CVD graphene synthesis techniques can be as high as 1000° C. The nearly 1000° C. temperature and costly metal-contained substrate (such as Cu or Ni) limit the using of CVD graphene synthesis technique. Besides, even though the as-grown graphene size can be as large as an A4 size, producing the graphene in batch quantity in the horizontal-type tube furnace is not continuously producing, which results in more than 100 dollars per inch cost, and thus not able to be applied in the market.

Therefore, the industry needs to develop an apparatus which continuously synthesizes large area carbon film or inorganic material film, such that the apparatus can keep the cost low as well as has good efficiency, thereby producing large area carbon film or inorganic material film.

### BRIEF SUMMARY

A preferred embodiment of the present invention is to provide an apparatus for continuous synthesis of carbon film or inorganic material film. The apparatus includes an external chamber, a substrate transporting apparatus, a substrate with metal, a temperature controller, a vacuum system, and a gas source controller. The external chamber has a gas intake gate and a gas exhaust gate installed thereon. The substrate transporting apparatus is disposed inside the external chamber and includes a rolling-out member, a plurality of rollers, a rolling-in member, and a moving path. The substrate with metal is conveyed along the moving path. A temperature controller is correspondingly disposed above or under the substrate transporting apparatus. When the substrate with metal passes through the temperature controller, the temperature controller heats the substrate with metal. A vacuum system is connected to the external chamber and inhales a gas through the gas intake gate and exhausts the gas through the gas exhaust gate. A gas source controller is connected to the external chamber and controls a supply of the gas. The gas includes a carbon source or an inorganic material source.

Another preferred embodiment of the present invention is to provide a method for continuous synthesis of carbon film or inorganic material film. The method includes the following steps. First, provide a chemical vapor deposition external chamber and a substrate transporting apparatus, wherein the substrate transporting apparatus is installed in the chemical vapor deposition external chamber and comprises a rolling-out member, a plurality of rollers, a rolling-in member, and a moving path. The chemical vapor deposition external chamber further has a pre-treatment chamber and a processing chamber disposed along the moving path, a pre-treatment processing is performed in the pre-treatment chamber, and then one side or two sides of a substrate with metal is/are formed with a carbon film or an inorganic material film in the processing chamber; the substrate with metal is conveyed along the moving path. Second, provide a processing gas including a carbon source or an inorganic material source, wherein the processing gas forms a carbon film or an inorganic film on one side or two sides of the substrate with metal. Third, perform a cooling process to the carbon film or the inorganic film.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic diagram showing the synthesizing time, gas type, and the temperature according to the present invention;

FIG. 2 is a schematic view of a preferred embodiment of the apparatus for continuous synthesis of carbon film or inorganic material film according to the present invention;

FIG. 3 is a schematic view of another preferred embodiment of the apparatus for continuous synthesis of carbon film or inorganic material film according to the present invention;

FIG. 4 is a schematic view of yet another preferred embodiment of the apparatus for continuous synthesis of carbon film or inorganic material film according to the present invention; and

FIG. 5 is a schematic view of still another preferred embodiment of the apparatus for continuous synthesis of carbon film or inorganic material film according to the present invention.

### DETAILED DESCRIPTION

The apparatus and method for continuous synthesis of carbon film or inorganic material film can be applied to the physical vapor deposition, chemical vapor deposition (CVD), epitaxial growth method, molecular beam epitaxy method, or single atomic layer deposition method. The preferred embodiment of the present invention uses the CVD method to continuously synthesize carbon film or inorganic film in a substrate with metal as an illustration; however, all other methods which can continuously synthesize carbon film or inorganic material film do not depart from the spirit of the present invention. The so-called carbon film or inorganic material film can be a carbon material such as graphene, and the substrate with metal can be a metal-contained substrate or a substrate having a metal thin film.

First, supply hydrogen gas to the CVD reactor. The gas pressure of the hydrogen gas is within a standard condition field 10 mTorr-760 Torr, preferably 760 Torr, fixed flowing rate 5-1000 sccm (standard cubic centimeter per minute), preferably 50 sccm, supplying time 5 sec-2 hr, preferably 50 minutes. The substrate with metal is done with thermal annealing at 150-1300° C., typically 1000° C., and the thermal annealing time is 5 secs-2 hrs, preferably 40 mins, so that the organic substance and oxide can be removed from the surface of the substrate. And then a mixture gas having carbon source or inorganic material source is supplied to the system to grow the carbon film or inorganic film at 150-1300° C., preferably 1000° C. The flow rate of the mixture gas including the carbon source or inorganic source is around 5-1000 sccm, preferably 60 sccm, and the flow rate of the hydrogen gas is 15 sccm.

The carbon source or the inorganic source used in the preferred embodiment of the present invention can be formed by pyrolyzing any one of the gas phase carbon-based precursor, the liquid phase carbon-based precursor, or the solid phase carbon-based precursor. The carbon-based precursor is selected from a group consisting of methane, ethylene, acetylene, ethanol, benzene, methanol, carbon-based polymer, nano-carbon material, and the mixture thereof. The carbon source or the inorganic material source is selected from a group consisting of nitrogen, boron, and the mixture thereof. The inorganic material source is selected from a group consisting of boron nitride, molybdenum disulfide, zinc sulfide, zinc telluride, zinc selenide, tris bismuth selenide, bismuth telluride, and the mixture thereof. The metal of the substrate is selected form a group consisting of copper, iron, cobalt, nickel, gold, silver, platinum, rubidium, and the mixture thereof. The substrate material is selected from a group consisting of silicon oxide, quartz, sapphire, boron nitride, glass, metal, semiconductor, and the mixture thereof.

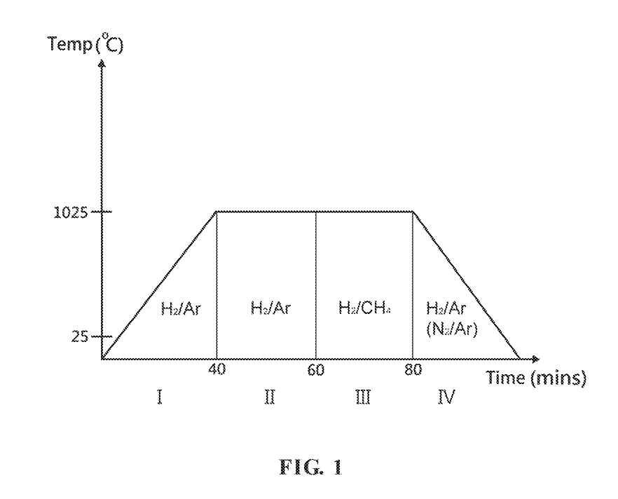

Referring to FIG. 1, there are approximately three processing steps of the method for continuous synthesis of carbon film or inorganic material film according the present invention to complete the whole processing. The first step is a hydrogen gas pre-treatment. A mixture gas containing hydrogen, such as hydrogen gas and argon gas, is supplied to the substrate (as shown in FIG. 1, roman numerals I and II) to pre-treat the surface of the substrate for pre-reduction. And then, in the second step (as shown in FIG. 1, roman numerals III), a reaction gas (methane, hydrogen, argon) is supplied during the growing process. The carbon source or the inorganic material source can select not only from methane, but also from acetylene or ethylene, thereby growing carbon film or inorganic material film. The third step is a cooling step (as shown in FIG. 1, roman numerals IV), a mixture gas containing hydrogen, such as hydrogen gas and argon gas, or inert gas, such as nitrogen or argon, is supplied to cool down the system and stabilize the carbon film or the inorganic film. In the first step, the substrate with metal is under a 40 mins heating treatment in an environment filled with hydrogen gas to increase the environmental temperature, where the substrate with metal is situated from room temperature to 1025° C. And then, in the second step, supply the reaction gas 20 mins in a constant temperature 1025° C. to grow the carbon film or the inorganic film on the substrate with metal. At last, in the third step, supply the argon and proceed 40 mins of cooling down treatment to the substrate with metal to eventually cool down the temperature from 1025° C. to under room temperature 25° C.

The apparatus for continuous synthesis of carbon film or inorganic material film according to the present invention is a roll-to-roll device, which uses roller transferring as a base structure to retrieve/release, transfer, and do the auxiliary processing to the soft substrate. The roll-to-roll device uses roller to control the moving of the soft substrate, and keep a stable transferring speed. By controlling all kinds of parameters, the precise processing operation can achieved. The substrate with metal can be a flexible soft substrate which is several tens of meters in length and can be rolled as a cylindrical shape. The substrate can continuously unfold during the synthesis of the carbon film or the inorganic material film. The carbon source or the inorganic material source of the mixture gas in the reactor can be deposited on the surface of the substrate which continuously passes through to form a carbon film or an inorganic material film. The substrate is cooled to 25-300° C., preferably 25° C., and then is rolled in the cylindrical shape. Thus, the method of the present invention is a roll-to-roll method which continuously synthesizes carbon film or inorganic material film.

The roll-to-roll continuously synthesizing carbon film or inorganic material film method has the advantages of large area, high yield, and low cost, which is one of the main technique for continuously manufacturing the commercial product. However, when using the roll-to-roll device, a corresponding chamber needs to be installed as well to correspond to the processing method of the continuous synthesis of carbon film or inorganic material film, and the corresponding amount of vacuum pumps also needs to be set up to control the chemical deposition atmosphere of each chamber. Besides, buffer zones also need to be provided between each chamber to isolate the chemical deposition gas of different chamber.

Therefore, in the above mentioned apparatus for roll-to-roll continuously synthesizing carbon film or inorganic material film, the chemical deposition atmosphere in each chamber should be properly controlled since a plurality of chambers, vacuum pumps, and buffer zones are used. The other techniques, features and effects regarding the present invention are shown with the following four embodiments of apparatus and method of continuously synthesizing carbon film or inorganic material film.

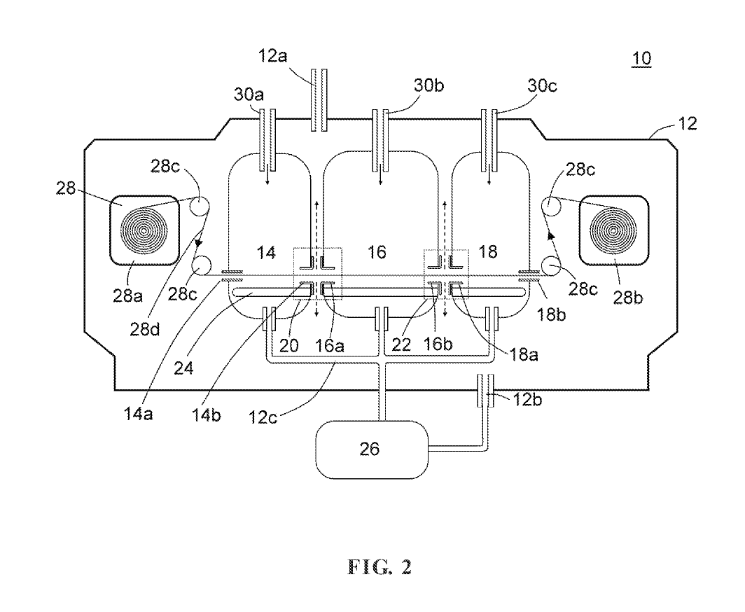

In the first preferred embodiment of the present invention, an apparatus with a roll-to-roll device and three processing chambers is used. The apparatus can continuously synthesize large area carbon film or inorganic material film. Please refer to FIG. 2. It is noted that FIG. 2 only shows the main elements of the apparatus 10; however, one skilled in the art should be able easily infer all the elements of the apparatus 10. Also, the FIG. 2 is used for illustration only, and the present invention is not limited thereto.

The apparatus 10 for continuously synthesizing carbon film or inorganic material film mainly has an external chamber 12, a substrate transporting apparatus 28, a vacuum system 26, a gas source controller 30a, 30b, 30c, a pre-treatment chamber 14, a processing chamber 16, a cooling chamber 18, a first buffer zone 20, a second buffer zone 22, and a temperature controller 24.

As shown in FIG. 2, the substrate transporting apparatus 28 is used for conveying the substrate with metal 28d to move along a moving path, and the moving path is shown as the arrow direction. The substrate transporting apparatus 28 has a rolling-out member 28a, a rolling-in member 28b, and a roller 28c. The substrate with metal 28d is rolled out from the rolling-out member 28a by the roller 28c, and moves along the moving path in the external chamber 12 through the roller 28c, and then finally is rolled up to form as a cylinder through the rolling-in member 28b. The rolling-in member 28a and the rolling-out member 28b are respectively installed at the upstream and downstream of the apparatus 10. The rolling-in member 28a and the rolling-out member 28b are suitable for rolling the substrate, and two ends of the substrate with metal 28d are respectively fixed to the rolling-in member 28a and the rolling-out member 28b. By the rotation of the rolling-in member 28b, the substrate with metal 28d will continuously be transferred from the rolling-out member 28a to the rolling-in member 28b. The rolling-out member 28a and the rolling-in member 28b can be composed of bearing and turning wheel (not shown in the FIGS.). Wherein the bearing is pivotally installed on the apparatus 10, and the turning wheel is installed on the bearing. The substrate with metal 28d is rolled up on the turning wheel. The rotation of the rolling-in member 28b can be achieved by attaching the rolling-in member 28b to a driving element (not shown in the FIGS.), such as connecting the bearing of the rolling-in member 28b in a proper gear configuration to a motor, so as to bring the rotation of the rolling-in member 28b by the motor.

The aforementioned external chamber 12 has a gas intake gate 12a, and gas exhaust gate 12b, and the interior of the external chamber 12 is installed with a pre-treatment chamber 14, a processing chamber 16, and a cooling chamber 18. The pre-treatment chamber 14, the processing chamber 16, and the cooling chamber 18 can be installed along the moving path of the substrate with metal 28d. The substrate with metal can sequentially pass through the pre-treatment chamber 14, the processing chamber 16, and the cooling chamber 18 along the moving path, and a temperature controller 24 can heat up the substrate with metal 28d.

A first buffer zone 20 is provided between the pre-treatment chamber 14 and the processing chamber 16; a second buffer zone 22 is provided between the processing chamber 16 and the cooling chamber 18. The first buffer zone 20 is used to isolate the gas communication between the pre-treatment chamber 14 and the processing chamber 16; the second buffer zone 22 is used to isolate the gas communication between the processing chamber 16 and the cooling chamber 18. The gas in the first buffer zone 20 flows toward a direction away from the outlet 14b of the pre-treatment chamber 14 and the inlet 16a of the processing chamber 16; the gas in the second buffer zone 22 flows toward a direction away from the outlet 16b of the processing chamber 16 and the inlet 18a of the cooling chamber 18. Therefore, the cross-contamination between the pre-treatment chamber 14, the processing chamber 16, and the cooling chamber 18 can be avoided. The flowing rate of the gas in the first buffer zone 20 and the second buffer zone 22 is about 0.05 L/min-1000 L/min.

The pre-treatment chamber 14, the processing chamber 16, and the cooling chamber 18 are installed along the moving path of the substrate with metal 28d, and thus the substrate with metal 28d can sequentially pass through the pre-treatment chamber 14, the processing chamber 16, and the cooling chamber 18 along the moving path.

Being driven by the rolling-out member 28a and the rolling-in member 28b, the substrate with metal 28d can sequentially pass through the pre-treatment chamber 14, the processing chamber 16, and the cooling chamber 18. The substrate enters the inlet 14a of the pre-treatment chamber 14. The pre-treatment chamber 14 is degassed to lower the gas pressure and heated up for 40 mins to increase the environmental temperature of the pre-treatment chamber where the substrate is situated from room temperature to 1025° C. Then, pre-treat the substrate with metal 28d under the constant temperature 1025° C. for 20 mins to remove the organic material and the oxide. The hydrogen gas is led to the pre-treatment chamber 14 through the gas source controller 30a. The hydrogen gas is supplied in a constant flowing rate for 50 mins, and the flowing rate is 50 sccm (Standard cubic centimeter per minute), which means the flowing rate is 50 cubic centimeter per minute under standard condition (pressure 760 Torr). The pre-treatment chamber 14 can do the first step pre-treating to the substrate with metal 28d. After the first step pre-treatment is done, the substrate with metal leaves from the outlet 14b of the pre-treatment chamber 14 and enters the processing chamber 16 through the inlet 16a. When the substrate moves to the processing chamber 16, the chemical deposition process is applied to the substrate with metal 28d, and the synthesis of the carbon film or the inorganic film proceeds. The substrate with metal 28d will first pass through the first buffer zone 20 between the pre-treatment chamber 14 and the processing chamber 16 before entering the processing chamber 16. The first buffer zone 20 is an extraction buffer zone. By the extraction or degassing procedure, a relative negative pressure will form at the outlet 14b and the inlet 16a, which can prevent the cross-contamination of the atmosphere between the pre-treatment chamber 14 and the processing chamber 16. The dotted line arrow in FIG. 2 shows the gas flowing direction of the extraction. In addition, the temperature inside the pre-treatment chamber 14 is adjusted by the temperature controller 24. The substrate with metal 28d enters into the processing chamber 16 having processing set parameters, for example, the processing chamber 16 is supplied with reaction gas (methane/hydrogen gas) at constant temperature 1025° C. for 20 mins to form a carbon film or an inorganic material film at the substrate with metal 28d. The reaction gas (methane/hydrogen gas) is led to the processing chamber 16 by the gas source controller 30b, and the large-area carbon film or inorganic material film is deposited on the substrate with metal 28d under a proper condition. The flowing rate of the methane is 60 sccm, while the hydrogen gas is 15 sccm. After the second step of synthesizing the carbon film or the inorganic material film is completed, the substrate with metal 28d having the carbon film or the inorganic material film leaves the processing chamber 16 from the outlet 16b and enters into the cooling chamber 18 from the inlet 18a. When the substrate with metal 28d moves to the cooling chamber 18, argon is supplied to the substrate with metal 28d and a 40 mins cooling process proceeds. The temperature eventually cools down from 1025° C. to under room temperature. The substrate with metal 28d enters the second buffer zone 22 between the processing chamber 16 and the cooling chamber 18 before entering the cooling chamber 18. The second buffer zone 22 is also an extraction buffer zone. By the extraction or degassing procedure, a relative negative pressure will form at the outlet 16b and the inlet 18a, which can prevent the cross-contamination of the atmosphere between the processing chamber 16 and the cooling chamber 16. The dotted line arrow in FIG. 2 shows the gas flowing direction of the extraction. Then, the substrate with metal 28d enters the cooling chamber 18, and great amount of argon is led into the cooling chamber 18 by the gas source controller 30c to proceed with 40 mins cooling down process to the substrate. The temperature eventually cools down from 1025° C. to room temperature. Finally, the substrate with metal 28d having the carbon film or the inorganic material film is rolled up by the rolling-in member 28b.

An extraction buffer zone (not shown in the figures) also exists between the inlet 14a of the pre-treatment chamber 14 and the outlet 18b of the cooling chamber 18. By the extraction or degassing procedure, a relative negative pressure will form at the inlet 14a and the outlet 18b, which can prevent the cross-contamination of the atmosphere in the pre-treatment chamber 14 and the cooling chamber 18 with the gas in the external chamber 12.

In other embodiments, not only methane, but also acetylene or ethylene, etc., can be used as the reaction gas providing carbon source or inorganic material source to form the carbon film or inorganic film. Besides, the temperature in the processing chamber 16 and the cooling chamber 18 can also be controlled by the temperature controller 24. The vacuum system 26 can also directly connect to the pre-treatment chamber 14, the processing chamber 16, and the cooling chamber 18. The vacuum system 26 can degas the reaction gas in the pre-treatment chamber 14, the processing chamber 16, and the cooling chamber 18 if needed, so as to keep those chambers in vacuum condition. Wherein, the vacuum system 26 can use the conventional combination of mechanical pump and diffusion pump.

As shown in FIG. 2, the gas source controller 30a, 30b, 30c controls the gas in the pre-treatment chamber 14, the processing chamber 16, and the cooling chamber 18. The gas source controller 30a, 30b, 30c are installed inside the external chamber 12 for providing the gas used in synthesizing the carbon film or the inorganic material film. It is noteworthy that, when the present invention is synthesizing the carbon film or the inorganic material film, the operation parameters of the gas source controller 30a, 30b, and 30c are different. Wherein, the operation parameter of the 30a is a mixture gas containing hydrogen gas, and the flowing rate is 0.5-500 sccm, preferably 20 sccm. The 30b is a mixture gas containing carbon source CH₄/H₂/Ar, wherein the carbon source is 0.5-800 sccm, preferably 20 sccm, the Hydrogen gas is 0.5-1000 sccm, preferably 20 sccm, the Ar gas is 0.5-1000 sccm, preferably 900 sccm. The 30c is argon gas or nitrogen gas 0.5-1000 sccm, preferably 500 sccm for argon gas. The gas source controllers 30a, 30b, 30c are used to control the operation parameter of supplying at least one gas source in chemical deposition. Wherein, the operation parameters of each of the gas source controllers 30a, 30b, and 30c are different from one another. Thus, when doing the chemical deposition, the gas and the gas mixing ratio for the chemical deposition can be selected according to the actual need for the processing of the chemical deposition.

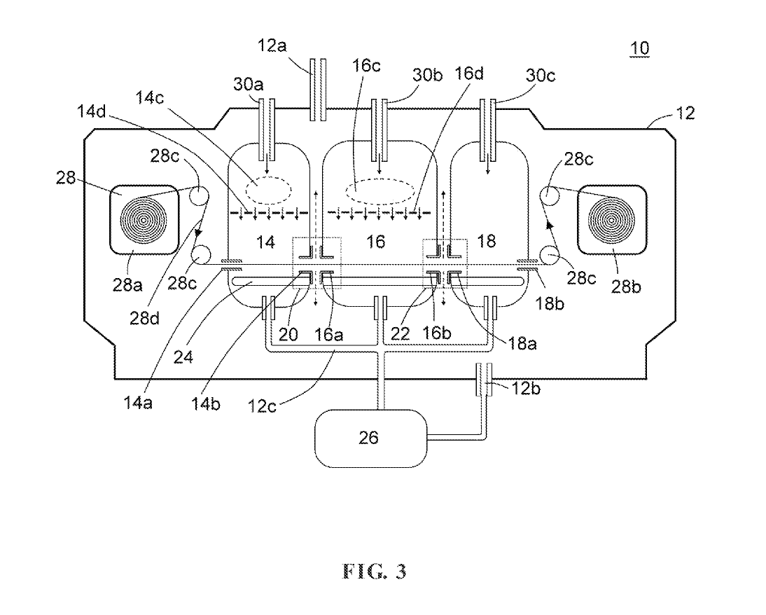

As shown in FIG. 3, which is a second preferred embodiment of the present invention. The difference compared to the first preferred embodiment lies in that, the present embodiment uses Plasma Assisted Chemical Vapor Deposition (PACVD) to continuously synthesize carbon film or inorganic material film on a substrate with metal 28d. The PACVD mainly uses the microwave plasma auxiliary system to collocate with the continuous Roll-to-Roll device to continuously synthesize carbon film or inorganic film on the substrate with metal 28d under low temperature. The plasma can help to do the pyrolysis to the carbon source or the inorganic material source to assist the synthesis at low temperature.

In the present embodiment, the pre-treatment chamber 14 further includes a first plasma source 14c and a first filter 14d. The processing chamber 16 includes a second plasma source 16c and a second filter 16d. In the present embodiment, the plasma source provides a gas ionization environment which can lower the processing temperature of continuously synthesizing the carbon film or the inorganic material film by the formation of the plasma. In the PACVD of the present embodiment, the electric field can electrolyse the gas to generate electrons and ions. When those electrons accelerate by the radio frequency or the microwave, those electrons will collide with the gas to generate more electrons and ions, and plasma will be generated accordingly. The filter is installed between the plasma source and the substrate with metal 28d, which can diminish the ions bombard and reduce the UV photon damage to the graphene. In the present embodiment, the substrate with metal 28d is pre-treated in the pre-treatment chamber 14. The pre-treatment chamber 14 is degassed to lower the gas pressure, and then proceeds with 40 mins heating process to increase the environmental temperature from room temperature to 1025° C. Then, use hydrogen gas plasma to pre-treat the substrate with metal 28d for 20 mins under a constant temperature 1025° C. to remove the organic material and the oxide from the substrate with metal 28d. In other words, the plasma assists the electrolysis of the hydrogen gas, which not only helps to lower the processing temperature, but also forms the hydrogen reactive ion group to do the reduction to the surface of the substrate with metal 28d. Then, proceed with the deposition process on the substrate with metal 28d in the processing chamber 16, which means supplying reaction gas (methane, hydrogen gas, argon gas) to the processing chamber 16. The carbon source or the inorganic material source can be methane, acetylene, or ethylene, etc., so that the carbon film or the inorganic material film can be synthesized on the substrate with metal 28d in the deposition process.

The PACVD is used in the processing chamber 16 to continuously synthesize carbon film or inorganic material film on the substrate with metal 28d. That is to say, providing a mixture gas of methane and hydrogen gas as the carbon source or the inorganic material source to the processing chamber 16 of the PACVD, and forming the graphene film at 1000. The flowing rate of the methane is 60 sccm, the flowing rate of the hydrogen gas is 15 sccm, and the 2.45 GHz microwave is supplied to produce the plasma. The plasma provides the energy for the electrolysis of the carbon source or the inorganic material source, and the electrolyzed carbon source or the inorganic material source gas will deposit on the surface of the substrate with metal 28d, and thus a carbon film or an inorganic material film can be synthesized on the surface of the substrate with metal 28d. At last, a cooling process is applied to the carbon film or the inorganic material film in the cooling chamber 18 to cool down the temperature to stabilize the carbon film or the inorganic material film.

However, the aforementioned first plasma source 14c, the first filter 14d, the second plasma source, and the second filter 14d are only auxiliary to the present invention, and thus the present invention is not limited thereto.

It is noteworthy that, the FIGS. 2 and 3 of the present invention disclose a continuous roll-to-roll deposition apparatus, but the present invention is not limited thereto. The substrate transporting apparatus 28 of the present invention can be a conventional conveyor system. Besides, the substrate with metal 28d is not limited as consecutive belt shape, the substrate with metal 28d can also be a sheet with specific size and held by a tray. The tray can further be installed on the conveyor system for conveying the substrate, and the processing chamber is installed on the moving path of the substrate. Based on the those described above, an apparatus with continuous processing chamber of the present invention can be established as long as the processing chamber according to the present invention is installed on any known continuous substrate conveying device.

As shown in FIGS. 2 and 3, the pre-treatment chamber 14, the processing chamber 16, and the cooling chamber 18 can be connected to the vacuum system 26 via the chamber exhausting tube 12c, and the opening/closing of the chamber exhausting tube 12c can be done by setting valves at any random place, according to the user's demand.

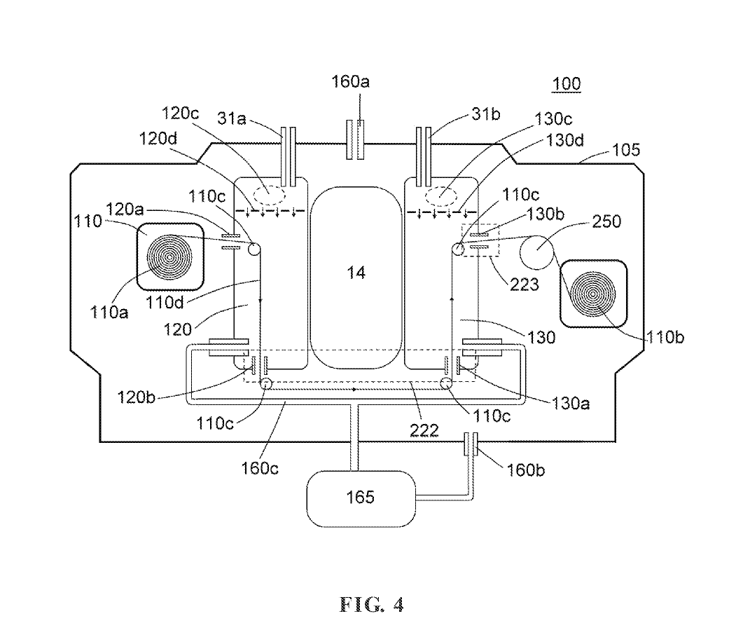

Referring to the third preferred embodiment of the present invention, as shown in FIG. 4 which illustrates an apparatus having two chambers for continuous synthesis of carbon film or inorganic material film, it is noteworthy that, even though only the main elements of the apparatus 100 are shown, however, one skilled in the art should be able easily infer all the elements of the apparatus 100. Also, the FIG. 4 is used for illustration only, and the present invention is not limited thereto.

FIG. 4 is the third preferred embodiment of the present invention. The apparatus 100 is a continuous roll-to-roll carbon film or inorganic material film synthesizing apparatus. The apparatus 100 mainly has an external chamber 105 having a gas intake gate 160a and a gas exhaust gate 160b; at least one pre-treatment chamber 120 and a processing chamber 130 is installed inside the external chamber 105. The apparatus 100 further includes a substrate transporting apparatus 110 which consists of a rolling-out member 110a, a rolling-in member 110b, and a roller 110c. The apparatus 100 also includes a vacuum system 165, a gas source controller 31a and 31b, a first buffer zone 222, a second buffer zone 223, a temperature controller 14, and a cooling wheel 250. The apparatus 100 uses two chambers to complete the preparation of the carbon film or the inorganic material film.

As shown in FIG. 4, the same features of the first and second embodiments as compared to the third embodiment are not repeated hereinafter. The temperature controller 14 is installed between the pre-treatment chamber 120 and the processing chamber 130. The pre-treatment chamber 120 and the processing chamber 130 are installed on a moving path of a substrate with metal 110d. That is to say, the substrate with metal 110d will sequentially pass through the inlet 120a and outlet 120b of the pre-treatment chamber 120, the inlet 130a and outlet 130b of the processing chamber 130 by the driving of the aforementioned rolling-out member 110a and the rolling-in member 110b. When the substrate with metal 110d moves in the processing chamber 130, the carbon film or the inorganic material film deposition will proceed on the substrate with metal 110d. The first buffer zone 222 and the second buffer zone 223 have the similar functions as the first buffer zone 20 and the second buffer zone 22 in the FIGS. 2 and 3, and thus not repeat hereinafter.

An extraction buffer zone (not shown in the figures) also exists between the inlet 120a of the pre-treatment chamber 120 and the outlet 130b of the processing chamber 130. By the extraction or degassing procedure, a relative negative pressure will form at the inlet 120a and the outlet 130b, which can prevent the cross-contamination of the atmosphere in the pre-treatment chamber 120 and the processing chamber 130 with the gas in the external chamber 105

The embodiment as shown in FIG. 4, the substrate with metal 110d is pre-treated with a hydrogen plasma in the pre-treatment chamber 120. The mixture gas of hydrogen gas and argon gas is supplied to the pre-treatment chamber 120 at 600° C., wherein the max plasma power is 150 W.

Then, the substrate with metal 110d being treated by the hydrogen gas plasma 120c and the filter 120d eventually leaves the pre-treatment chamber 120 and enters the processing chamber 130. Similarly, the substrate with metal 110d also being treated by the hydrogen gas plasma 130c and the filter 130d in the processing chamber 130, and the whole treating process is in vacuum condition. It is noteworthy that, the substrate with metal 110d grows carbon film or the inorganic material film in the processing chamber 130 is under 1000° C., 200 mTorr-10 Torr pressure, and the reaction gas is supplied in a form of shower, wherein the reaction gas is a mixture gas of methane, hydrogen gas, and argon gas. The thickness of the substrate with metal 110d is 25 μm, the max width is 21 μm. The operating area for film growth is 70 cm×30 cm, the minimum rolling speed is 5 mm/s, while the maximum rolling speed is 100 mm/s. Besides, the height of the plasma source and the substrate with metal 110d is adjustable. It is noted that, a cooling wheel 250 is provided between the processing chamber 130 and the rolling-in member 110b in the present embodiment, which cools down the substrate with metal 110d having the carbon film or the inorganic material film to under 200° C. by air cooling or water cooling method, and the rolling-in member 110b will receive the substrate with metal 110d afterward.

It is noted that, in the embodiment as shown in FIG. 4, the vacuum system 165 exhausts or intakes the processing gas by the gas intake gate 160a and the gas exhaust gate 160b of the external chamber 105 to keep the vacuum condition. In other embodiments, the vacuum system 165 also has pipelines individually connected to each chambers, as shown in FIG. 4, the chamber exhaust tube 160c is directly connected to the pre-treatment chamber 120 and the processing chamber 130. If necessary, the processing gas in the pre-treatment chamber 120 and the processing chamber 130 can be respectively extracted to keep the vacuum condition. The chamber exhaust tube 160c can also be set valves for the adjustment purpose.

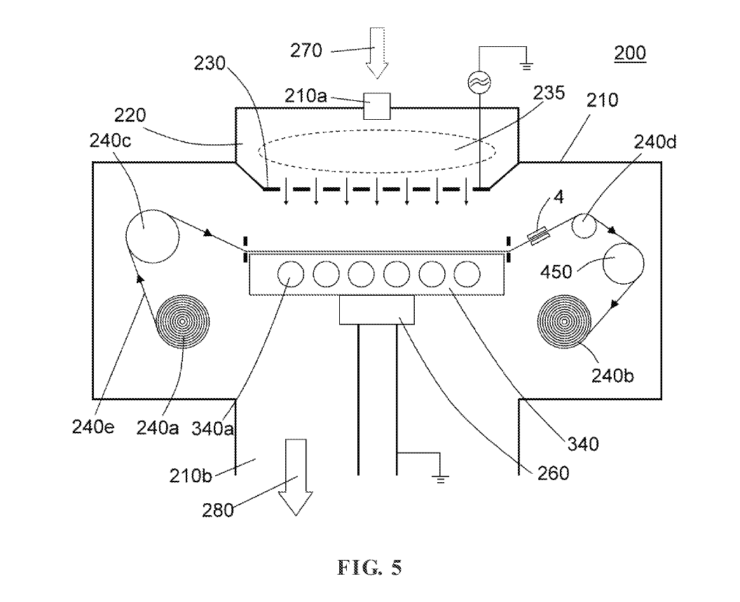

Refer to FIG. 5, which is an illustration of an apparatus with single chamber. FIG. 5 shows the fourth preferred embodiment of the apparatus 200 according to the present invention. It is noted that FIG. 5 only shows the main elements of the apparatus 200; however, one skilled in the art should be able easily infer all the elements of the apparatus 200. Also, the FIG. 5 is used for illustration only, and the present invention is not limited thereto.

In the embodiment shown in FIG. 5, the apparatus 200 is a continuous roll-to-roll carbon film or inorganic material film synthesizing apparatus. The apparatus 200 mainly includes a processing chamber 210, a gas source controller (not shown in the FIG.), and a plasma generator 220 with a filter 230. It is noted that, the apparatus 200 uses single chamber to complete the preparation process of the carbon film or the inorganic material film.

As shown in FIG. 5, the processing chamber 210 includes a gas intake gate 210a and a gas exhaust gate 210b. The top of the processing chamber 210 is connected to the plasma generator 220 with a filter 230. At least one substrate transporting apparatus 240, a vacuum system 260, a cooling wheel 450, and a temperature controller 340 are installed inside the processing chamber 210. Wherein, the plasma generator 220 with a filter 230 generates a plasma 235 inside the processing chamber 210. In the present embodiment, the substrate transporting apparatus 240 includes a rolling-out member 240a, a rolling-in member 240b, a roller 240c, and a cooling wheel 450, for conveying the substrate with metal 240e. Wherein, the processing gas can enter or leave the processing chamber 210 through the gas intake gate 210a and the gas exhaust gate 210b toward the direction of the arrows 270 and 280. Wherein, the temperature controller 340 includes a heating lamp 340a for heating up the substrate with metal 240e. The cooling wheel 450 is used to convey and cool down the substrate with metal 240e having the carbon film or the inorganic material film.

In the embodiment shown in FIG. 5, the substrate with metal 24e is formed the carbon film or the inorganic material film in the processing chamber 210 under 600-1000° C., 200 mTorr-10 Torr pressure, and the reaction gas is supplied in a form of shower. Wherein, the reaction gas is a mixture gas of methane, hydrogen gas, and argon gas. The thickness of the substrate with metal 240e is 25 μm, the max width is 21 μm. The operating area for film growth is 70 cm×30 cm, the minimum rolling speed is 5 mm/s, while the maximum rolling speed is 100 mm/s. Besides, the height of the plasma source and the substrate with metal 240e is adjustable. It is noted that, the cooling wheel 450 in the present embodiment cools down the substrate with metal 240e having the carbon film or the inorganic material film to under 200° C. by air cooling or water cooling method, and the rolling-in member 240b will receive the substrate with metal 240e afterward.

In the embodiment as shown in FIG. 5, the substrate with metal 240e can be replaced with a metal such as copper or nickel foil pre-coated with a layer of carbon film structure (for example, amorphous carbon: sputter carbon layer, PMMA, etc.). Then, a mixture gas of hydrogen gas and argon gas (or gas with hydrogen) is supplied to the processing chamber 210 as the reaction gas at 800-1000° C. to transform the carbon layer on the copper foil into a graphene structure. Then, the copper foil with graphene structure accompanied with the continuous roll-to-roll system to achieve the goal of continuously synthesizing large area graphene. Besides, a tungsten heating rod can also be used to scam the continuous copper foil to encourage the surface of the copper or nickel foils mentioned above to transform into graphene.

Furthermore, the present embodiment uses the high temperature tungsten to do a micro area heating on the copper foil covered with graphene. A carbon source is supplied in this process, which further optimize the defect cause by the incomplete bonding between the atoms when the graphene is crystallized. This process increases the graphene coverage and fixes the defect of the graphene to improve the quality of the graphene. Partial or regional heating can solve the problem of hard to control the uniformity and the coverage rate. Besides, the present invention provides a heating source in the central position, which can help to provide an even heating section at an adjustable temperature range 500-900° C.

Besides, the apparatus which continuously synthesizes film as shown in the aforementioned embodiment accompanied with a high uniformity surface-shaped plasma and special filter can solve the problem of bad conductivity of the growing of the graphene caused by the damage to the graphene due to ion bombardment and UV during the plasma graphene growing process.

Besides, the continuous carbon film or inorganic material film synthesizing apparatus of the present invention can further include a transfer device for transferring carbon film or inorganic material film. Besides, the aforementioned apparatus of the present invention can further includes a micro heating unit 4. The micro heating unit 4 is mainly composed of tungsten, which is used as a second temperature controller and installed before a cooling device such as the cooling chamber or the cooling wheel. The tungsten does a micro area heating on the copper foil covered with graphene.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. An apparatus for continuous synthesis of carbon film or inorganic material film, comprising:
an external chamber including a gas intake gate and a gas exhaust gate;
a substrate transporting apparatus installed in the external chamber, comprising a rolling-out member, a plurality of rollers, a rolling-in member, and a moving path; a substrate with metal being conveyed along the moving path;
a temperature controller being correspondingly disposed above or under the substrate transporting apparatus, wherein when the substrate with metal passes through the temperature controller, the temperature controller heats the substrate with metal;
a vacuum system connected to the external chamber, the vacuum system inhaling a gas through the gas intake gate and exhausting the gas through the gas exhaust gate;
a gas source controller connected to the external chamber and controlling a supply of the gas, wherein the gas includes a carbon source or an inorganic material source; and
a plasma system providing energy for pyrolyzing the gas.

2. The apparatus for continuous synthesis of carbon film or inorganic material film according to claim 1, wherein the substrate contains metal selected from a group consisting of copper, iron, cobalt, nickel, gold, silver, platinum and rubidium.

3. The apparatus for continuous synthesis of carbon film or inorganic material film according to claim 2, wherein the external chamber has at least a pre-treatment chamber and a processing chamber, a first buffer zone is situated therebetween.

4. The apparatus for continuous synthesis of carbon film or inorganic material film according to claim 3, further comprising a cooling chamber, wherein the pre-treatment chamber, the processing chamber and the cooling chamber are sequentially disposed along the moving path where the substrate with metal moves along, and a second buffer zone is situated between the processing chamber and the cooling chamber.

5. The apparatus for continuous synthesis of carbon film or inorganic material film according to claim 3 further comprising a cooling wheel, wherein the pre-treatment chamber, the processing chamber, and the cooling wheel are sequentially disposed along the moving path where the substrate with metal moves along, and the cooling wheel is used to cool the substrate with metal.

6. The apparatus for continuous synthesis of carbon film or inorganic material film according to claim 5, wherein the cooling wheel is an air cooling wheel or a water cooling wheel.

7. The apparatus for continuous synthesis of carbon film or inorganic material film according to claim 4, wherein a gas flowing rate of the first buffer zone and the second buffer zone is 0.05 L/min to 1000 L/min.

8. The apparatus for continuous synthesis of carbon film or inorganic material film according to claim 7, wherein the plasma system has a first plasma generating unit and a first filter installed therein; the processing chamber has a second plasma generating unit and a second filter installed therein.

9. The apparatus for continuous synthesis of carbon film or inorganic material film according to claim 8, wherein the first plasma generating unit and the second plasma generating unit are surface type plasma sources.

10. The apparatus for continuous synthesis of carbon film or inorganic material film according to claim 6, further comprising a micro heating unit installed in a position before the cooling wheel; wherein the micro heating unit is a high temperature tungsten wire and heats the substrate with metal.

11. The apparatus for continuous synthesis of carbon film or inorganic material film according to claim 7 further comprising a micro heating unit installed in a position before the cooling chamber; wherein the micro heating unit is a high temperature tungsten wire and heats the substrate with metal.

12. The apparatus for continuous synthesis of carbon film or inorganic material film according to claim 11 further comprising a transfer device removing the substrate with metal.

13. A method for continuous synthesis of carbon film or inorganic material film, comprising:
providing a chemical vapor deposition external chamber and a substrate transporting apparatus, wherein the substrate transporting apparatus is installed in the chemical vapor deposition external chamber and comprises a rolling-out member, a plurality of rollers, a rolling-in member, and a moving path; a substrate with metal being conveyed along the moving path;
providing a processing gas having a carbon source or an inorganic material source, wherein the processing gas forms a carbon film or an inorganic film on one side or two sides of the substrate with metal;
providing a plasma system which provides energy for pyrolyzing the processing gas; and
performing a cooling process to the carbon film or the inorganic film.

14. The method for continuous synthesis of carbon film or inorganic material film according to claim 13, wherein the chemical vapor deposition external chamber further has a pre-treatment chamber and a processing chamber disposed along the moving path, a pre-treatment processing is performed in the pre-treatment chamber, and then one side or two sides of the substrate with metal is/are formed with the carbon film or the inorganic material film in the processing chamber.

15. The method for continuous synthesis of carbon film or inorganic material film according to claim 14, wherein the substrate selected from a group consisting of a silicon oxide, a quartz, a sapphire, a boron nitride, a glass, a metal and a semiconductor substrate.

16. The method for continuous synthesis of carbon film or inorganic material film according to claim 14, wherein the substrate contains metal selected form a group consisting of copper, iron, cobalt, nickel, gold, silver, platinum and rubidium.

17. The method for continuous synthesis of carbon film or inorganic material film according to claim 14, wherein the carbon source or the inorganic material source is formed by pyrolyzing any one of a gas phase carbon-based precursor, a liquid phase carbon-based precursor, and a solid phase carbon-based precursor.

18. The method for continuous synthesis of carbon film or inorganic material film according to claim 17, wherein the carbon-based precursor is selected from a group consisting of methane, ethylene, acetylene, ethanol, benzene, methanol, carbon-based polymer, nano-carbon material, and the mixture thereof.

19. The method for continuous synthesis of carbon film or inorganic material film according to claim 13, wherein the carbon source or the inorganic material source is selected from a group consisting of nitrogen, boron, and the mixture thereof.

20. The method for continuous synthesis of carbon film or inorganic material film according to claim 13, wherein the inorganic material source is selected from a group consisting of boron nitride, molybdenum disulfide, zinc sulfide, zinc telluride, zinc selenide, tris bismuth selenide, bismuth telluride, and the mixture thereof.
